(19) United States
(12) Patent Application Publication
(10) Pub. No.: US 2007/0272828 A1
(43) Pub. Date: Nov. 29, 2007

(54) Method and apparatus providing dark current reduction in an active pixel sensor

(75) Inventor: Chen Xu, Boise, ID (US)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/439,180

(22) Filed: May 24, 2006

(51) Int. Cl. H01L 27/00

(52) U.S. Cl. 250/208.1

(57) ABSTRACT

An imager has one or more pixel circuits arranged to receive negatively biased control signals at one or more gates associated with charge holding regions to reduce dark current generation and flow.

### FIELD OF THE INVENTION

The invention relates generally to semiconductor devices, and more specifically to dark current reduction in an imaging device.

### BACKGROUND OF THE INVENTION

Optical communication and imaging systems generally require the conversion of light energy into electrical signals. The conversion of light energy to electrical signals involves the use of optical-to-electrical conversion circuits. An example of an optical-to-electrical conversion circuit is a complementary metal oxide semiconductor (“CMOS”) active pixel sensor circuit. Various active pixel sensor architectures are currently used, including photodiode and photo gate architectures. A photodiode active pixel sensor uses a photodiode, a reverse biased p-n junction, to produce an electrical signal that corresponds to the amount and type of light energy incident on the photodiode. Similarly, a photo gate active pixel sensor uses a capacitance formed by a capacitor, such as, for example, a polysilicon-oxide-silicon structure to generate charge proportional to the radiant power of the incident light. In both architectures, the photodetector converts the information carried by light energy into electrical signals.

A schematic of a conventional photodiode pixel circuit 20 of an active pixel sensor is shown in FIG. 1A. The photodiode pixel circuit 20 includes a reset transistor 22, a transfer transistor 30, a source follower transistor 24 and a row select transistor 26 in addition to a photodiode 28. The photodiode 28 generates charge in response to incident light energy. The generated charge is transferred via transfer transistor 30 to a floating diffusion region FD upon application of a transfer signal TX. The generated charge at the floating diffusion region FD is output to a column output line upon activation of the row select transistor 26 by a row select control signal RS. The reset transistor 22 is used to reset the pixel to a voltage VPIX when the reset control signal RST is applied.

Similarly, a conventional photo gate pixel circuit 40 of an active pixel sensor is shown in FIG. 1B. As with the photodiode pixel circuit 20, the photo gate pixel circuit 40 includes a transfer transistor 48, a reset transistor 42, a source follower transistor 44 and a row select transistor 46. However, in the illustrated photo gate pixel circuit 40, a photo gate 50 is used in place of a photodiode. Light energy is incident upon photo gate 50, resulting in the generation of charge. The generated charge is transferred via a transfer gate 48 to a floating diffusion region FD upon application of a transfer signal TX. The generated charge at the floating diffusion region FD is output to the column output line upon activation of the row select transistor 46 by the RS signal. Photo gate 50 may be biased using a photo gate signal PG.

Conventional photo gates and photodiodes are generally composed of multiple doped layers of silicon. For example, one exemplary conventional structure 70 containing a photodiode 71 is shown in FIG. 2. Photodiode 71 has a p-n-p-p junction region construction formed by a p-type surface layer 84, an n-type charge collection region 86 below region 84 and a p-type substrate 80. The p-type substrate 80 is formed of a p-type semiconductor base 82 and an overlaying p-type epitaxial layer 83. A floating diffusion region 85 adjacent a transfer gate 90 is also preferably n-type. Trench isolation regions 75 are formed in the p-type substrate 80 to isolate pixels one from another. A lower translucent or transparent insulating layer 95 is also formed over the structure 70 over which other imager structures are fabricated.

Generally, incident light penetrates into the p-type layer 84 and the n-type region 86 and excites electrons to jump from a valence band to a conduction band. The electrons are attracted to the n-type region 86 while the resulting holes appear in the p-type regions 80, 84. The output signal is proportional to the number of electrons to be extracted from the n-type region 86. The maximum output signal increases with increased electron capacitance or increased ability of the region 86 to hold electrons. The electron capacity of photodiodes typically depends on the doping level of the image sensor and the dopants implanted into the active layer.

Conventional photo gates and photodiodes do not, however, perfectly generate charge in response to incident light. Specifically, conventional photo gates and photodiodes generate dark current, which is current generated despite the absence of incident light energy. In other words, even when the photo gate or photodiode is not exposed to light, the photodetector may still accumulate charge in the form of dark current. Dark current is perceived as noise in the pixel output signal.

Dark current is caused, in part, by defects in silicon, such as bulk defects, interface defects and surface defects. Defects result in the generation of dark current by facilitating the separation of electrons and holes even when a photon is not present to excite an electron. Without a defect, an electron requires a photon or photons of sufficient energy to allow the electron to jump from a valence band to a conduction band. The energy required to jump from a valence band to a conduction band is the electron activation energy. When a defect is present, however, electrons need not jump directly from the valence band to the conduction band, but may instead jump through a series of intermediate states until arriving at the conduction band. The individual jumps to the intermediate states each require less energy than that defined by the electron activation energy. Background radiation may itself be sufficient to cause an electron to change states, thus creating current when no incident light is present. Defects near the surface are particularly susceptible to exterior radiation sources and hence prone to generating dark current.

Surface and interface-generated dark current may also occur in other parts of a pixel circuit. Specifically, dark current is generated in parts of a pixel dedicated to holding the generated charge before the charge is output to a floating diffusion region. This collection and hold region is often the photosensitive region, as in the case of the photo gate pixel circuit of FIG. 1B. However, the collection and hold region may also be a storage node separate from the photosensitive region. In either case, the dark current generated at the site of holding of the generated charge is of primary concern because generated dark current is added to the held charge during the entire time that the charge is held, and the charge may be held for a relatively long period of time. When a storage node exists, charge is generally held in the storage node for a period of time that is greater than the integration time. Thus, dark current generated in the storage node is more problematic than dark current generated in the photosensitive region during the integration time.

Various techniques to reduce dark current in photodiodes have been investigated. Some techniques have included reducing the size of the photon-absorbing region of an active pixel sensor and varying the doping degree in the multiple layers of a photodiode structure. However, such solutions inevitably result in some loss of functionality of the active pixel sensor. An active pixel sensor with improved reduced dark current is clearly desirable.

### BRIEF DESCRIPTION OF THE DRAWINGS

The invention will be more readily understood from the following detailed description of the invention which is provided in connection with the accompanying drawings, in which:

FIGS. 1A and 1B depict conventional pixel circuits of active pixel sensors;

FIG. 2 is a conventional structure containing a photodiode;

FIG. 3A depicts potential energy bands for a conventional active pixel sensor and FIGS. 3B and 3C depict potential energy bands for an active pixel sensor constructed according to an exemplary embodiment of the invention;

FIG. 4 is a timing diagram of an exemplary operating method for a photo gate pixel circuit according to an exemplary embodiment of the invention;

FIG. 5 is a schematic of a storage gate pixel circuit according to an exemplary embodiment of the invention;

FIG. 6 is a timing diagram of an exemplary operating method for a storage gate pixel circuit according to an exemplary embodiment of the invention;

FIG. 7 is a potential diagram for a storage gate pixel circuit according to an exemplary embodiment of the invention;

FIG. 8 illustrates a block diagram of a semiconductor CMOS imager according to an exemplary embodiment of the invention; and

FIG. 9 is an imaging system according to an exemplary embodiment of the invention.

### DETAILED DESCRIPTION OF THE INVENTION

As described above, surface and interface-generated dark current result from defects in the silicon layers of a photodetector (e.g., photodiode or photo gate) or in other storage areas of a pixel.

The surface defects in a pixel circuit facilitate the separation of electrons from holes near the surface of a semiconductor substrate, e.g., a silicon substrate, both in the photosensitive region and in a holding region. The free electrons generally travel to an n-type region of the pixel without recombining with holes. However, if the surface regions of the pixel were to include more holes than electrons, then many, even a majority of the electrons at the surface region could be recombined with holes before entering a charge collecting n-type region. The invention provides a method and structure for increasing recombination of electrons and holes in areas of a pixel which are subject to generation of dark current as explained below.

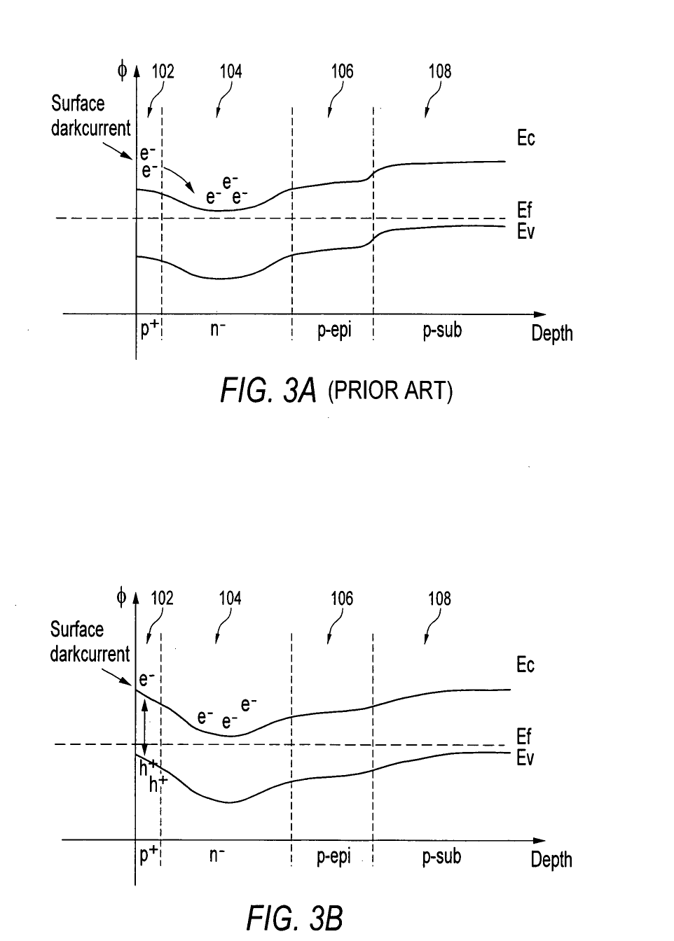

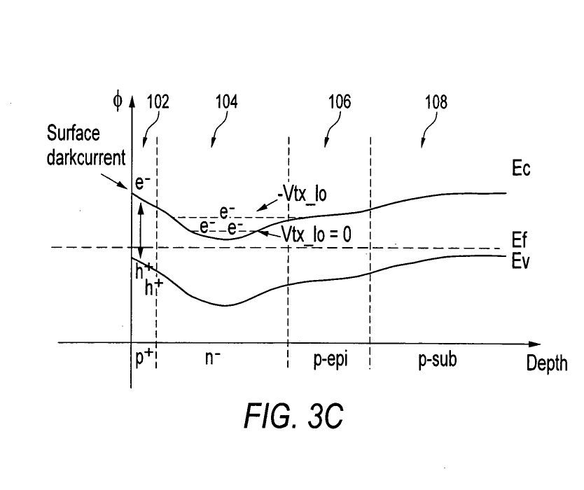

FIG. 3A shows the potentials of the valence Ev and conduction Ec bands in relation to the Fermi energy Ef for a p-n-p-p photodetector, comprising a p-type surface channel 102, an n-type charge accumulation region 104, an epitaxial p-type region 106 and a p-type substrate 108. In a p-n-p-p photodetector, the light sensitive region or the depletion region is located in the n-type and the epitaxial p-type regions 104, 106. In FIG. 3A, the horizontal axis represents the depth of the photodetector, with the surface of the photodetector being on the left. Generally, photons are incident to the photodetector and cause electrons e⁻ in the n-type region 104 and the epitaxial p-type region 106 to jump from the valence band Ev to the conduction band Ec. The free electrons e⁻ remain in the n-type region 104 while the resulting holes tend to migrate to the p type substrate region 108 (both electrons e⁻ and holes tend to migrate along their respective conduction Ec or valence Ev bands towards the Fermi energy Ef).

When background radiation is incident to the p-type surface channel 102, defects in the surface channel 102 may result in electrons e⁻ jumping from the valence band Ev to the conduction band Ec. These dark current electrons e⁻ migrate into the n-type region 104, nearer to their equilibrium Fermi state Ef. The generated holes do not generally recombine with the free electrons e⁻ before the electrons e⁻ flow into the n-type region 104. However, as shown in FIG. 3B, if the surface potential of the photodetector were made sufficiently negative, the Fermi energy Ef of the photodetector would shift so as to favor the collection of holes h⁺ near the surface of the photodetector. If the concentration of holes h⁺ increases sufficiently, many if not all of the electrons e⁻ generated by imperfections at the surface will recombine with the concentrated holes h⁺, thus efficiently reducing the surface generation of dark current.

However, by negatively biasing the photodetector, electrons e⁻ held in the n-type region 104 may have a tendency to leak through an associated transfer gate and into an adjacent floating diffusion region. FIG. 3C depicts the n-type region 104 charge capacity for a conventional or non-negatively biased transfer gate (indicated by the Vtx_lo=0 line). To avoid this reduction in charge capacity, the transfer gate is also negatively biased as shown by the −Vtx_lo line, thus raising the charge capacity of the n-type region 104 and preventing loss of electrons held in region 104 which are generated by the incident light. By negatively biasing both the photodetector and the transfer gate, dark current is reduced without contributing to leakage of held charge across the transfer gate.

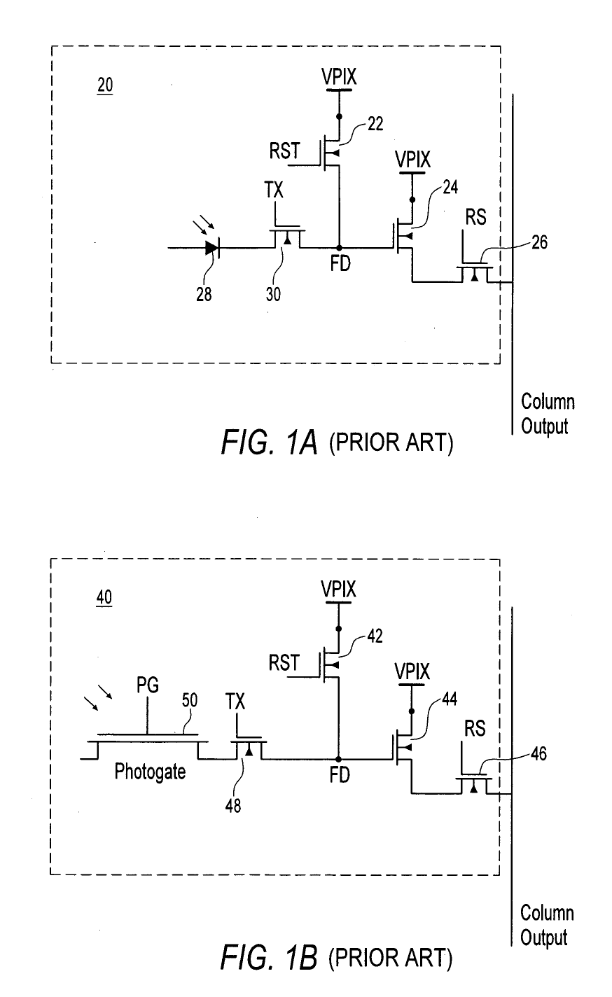

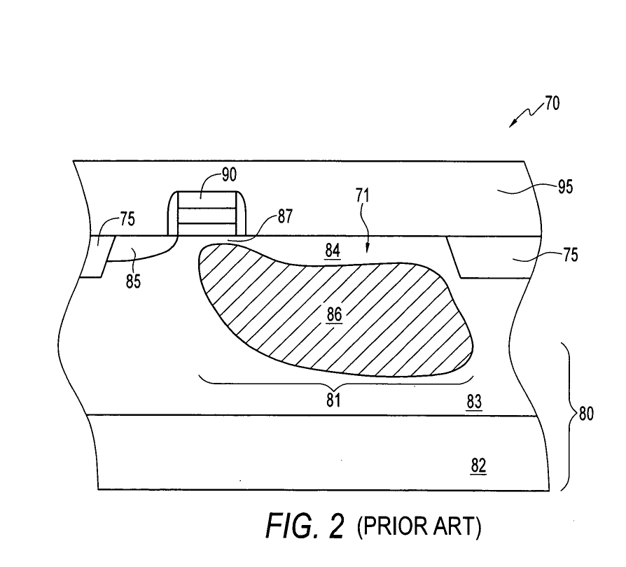

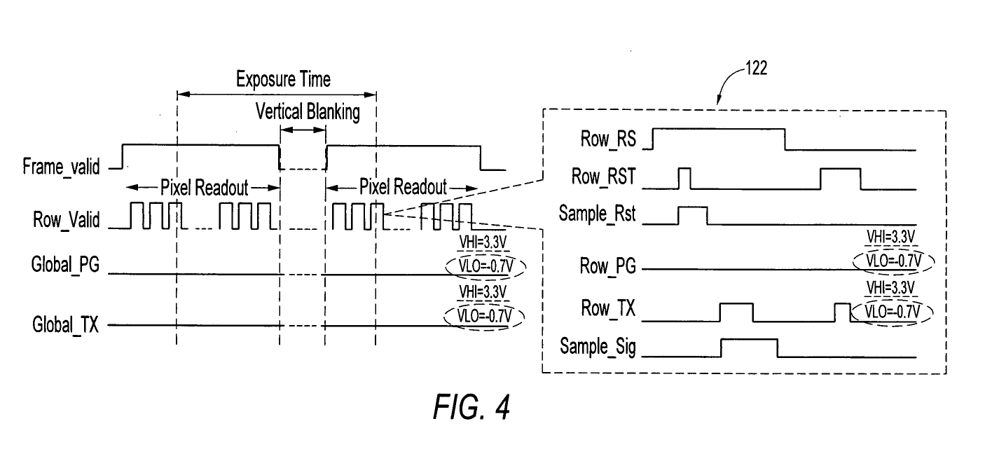

In one exemplary embodiment of the invention, as depicted by the timing diagram shown in FIG. 4, a method of operating a photo gate pixel circuit of an active pixel sensor (e.g. circuit 40 of FIG. 1B) is provided to negatively bias the photo gate pixel circuit. As mentioned above, the photo gate pixel circuit of FIG. 1B both generates charge and holds the generated charge at the site of the photo gate. Thus, minimizing the surface-generated dark current at the site of the photo gate is desirable. The FIG. 4 timing diagram depicts a time during which an entire array of photo gate pixel circuits is exposed to incident light, as indicated by the Frame_valid signal. A photo gate in the array is exposed to incident light virtually continuously except for the vertical blanking period. In the timing diagram, global control signals are control signals sent to all photo gate pixel circuits in a pixel array. Global control signals are only overridden by row-specific control signals, which are sent to all photo gate pixel circuits on a single row of the array. As explained above in connection with the desire to negatively bias both the photo gate and the transfer gate, the global photo gate signal Global_PG and the global transfer gate signal Global_TX are negatively biased throughout operation of the pixel array (for example, VLO=−0.7V). During the period of each frame, each row of pixels in the array is readout, as indicated by the Row-valid signal. Each pulse of the Row-valid signal controls the readout of an individual row of pixel circuits of the array. For each row readout, box 122 shows the additional row-specific signals that are pulsed for the photo gate pixel circuits in a row corresponding to the Row-valid pulse. For each photo gate pixel circuit, the row photo gate signal Row_PG remains negatively biased, thus reducing the generation of dark current by the photo gate. Charge is collected and held by the photo gate until the row in which the pixel circuit is located is selected via row select signal Row_RS. After the activation of the row select signal Row_RS, the floating diffusion region of the active pixel sensor is reset by the pulsing of a reset signal Row_RST. The voltage associated with the reset floating diffusion region is then readout through the source follower 44 and row select 46 transistors (FIG. 1B) and sampled to obtain a reset value during the period shown by the sample reset control signal Sample_Rst. While charge has collected in the photo gate, the transfer gate has remained negatively biased (see Row_TX) to prevent charge from the photo gate from passing through the transfer transistor 88. The negatively biased transfer gate prevents charge leakage into the floating diffusion region. After the floating diffusion region is reset and the reset signal is readout and sampled, the transfer gate signal Row_TX is pulsed high to transfer the generated charge from the photo gate 50 into the floating diffusion region for readout to the column output line through the source follower 44 and row select 46 transistors (FIG. 1B). The voltage associated with the charge stored in the floating diffusion region is then sampled in order to obtain an output level for the collected charge during the period shown by the sample signal control signal Sample_Sig.

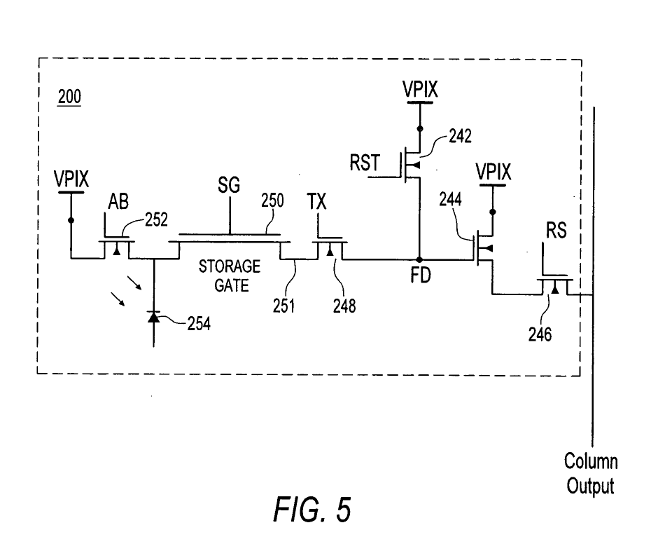

Another exemplary embodiment of the invention uses a storage gate pixel circuit of an active pixel sensor instead of a photo gate pixel circuit. FIG. 5 shows a storage gate pixel circuit 200. The storage gate pixel circuit 200 includes a reset transistor 242, a transfer transistor 248, a source follower output transistor 244 and a row select transistor 246. Photodiode 254 generates charge in response to incident light. The pixel also includes a storage gate transistor 250, a storage node 251, and an anti-blooming transistor 252. The generated charge is first collected in the photodiode 254 and is then transferred into the storage node 251 through storage gate transistor 250 upon activating storage gate control signal SG. Upon activating transfer control signal TX, the held charge is transferred from the storage node 251 to a floating diffusion region FD through transfer gate 248. The charge in the floating diffusion region FD is then output to a column output line upon activation of the row select transistor 246 by a row select control signal RS. The reset transistor 242 is used to reset the pixel to a voltage VPIX when the reset control signal RST is applied. Anti-blooming transistor 252 is used to draw excess charge away from the photodiode 254 (effectively resetting it) when the anti-blooming control signal AB is applied.

In this exemplary embodiment, it is desirable to reduce the surface-generated dark current at the site of the storage node. Although dark current will also be generated at the site of the photodiode during the integration time, the amount of dark current generated by the photodiode during the integration time is much smaller than the amount of dark current generated at the storage node. In this exemplary embodiment, the storage gate active pixel sensor 200, storage gate transistor 250 and transfer gate 248 are negatively biased to reduce dark current. Charge is generated and accumulated by the photodiode 254 during an integration period. At the end of the integration period, the accumulated charge is transferred to the storage node through storage gate transistor 250. Any additional current (such as dark current) that may be generated by the photodiode 254 after the transfer of charge to the storage node is not transferred through the storage gate transistor 250. While charge is held in the storage node 251, the negative bias applied to the storage gate 250 reduces any dark current generated near the surface of the storage gate 250 which could enter the storage node 251. Additionally, by negatively biasing the transfer gate 248, the full capacity of the storage node 251 is maintained and no leak current will pass through the transfer gate 248.

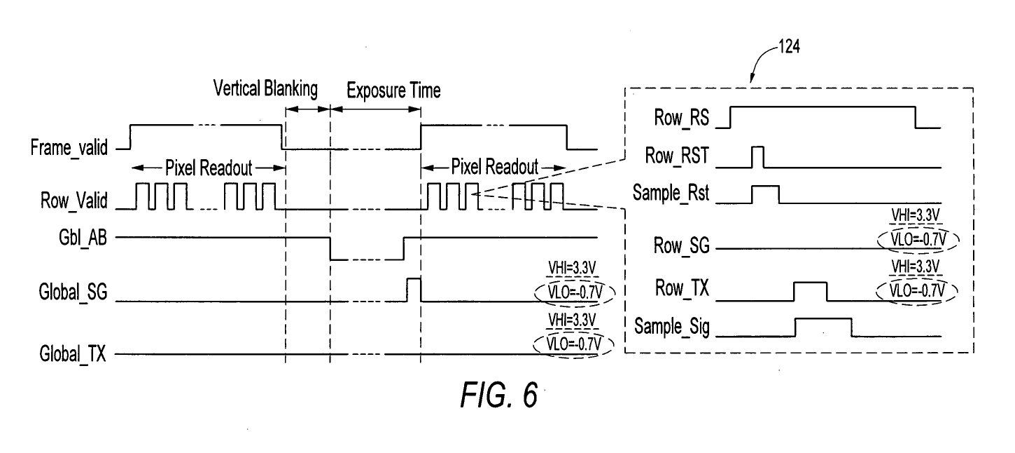

Timing diagram 300, shown in FIG. 6, further explains the operation of the storage gate pixel circuit 200. Initially, excess charge held in the photodiode is dumped during the vertical blanking period when anti-blooming signal Gbl_AB is active. Afterwards, when Gbl_AB goes low, the integration period begins, during which time the photodiode receives incident light energy and generates and accumulates charge. At the end of the integration period, global storage gate signal Global_SG, which was biased to a negative voltage, goes high to transfer the accumulated charge to the storage node 251 in all pixel circuits of an array. As soon as the transfer of charge to the storage node 251 is complete, global storage gate signal Global_SG is returned to a negatively biased state, for example, −0.7 V. Pixels are then read out row-by-row, each row corresponding to a Row_Valid pulse. When a Row_Valid pulse corresponds to the row in which a pixel circuit is located, the additional signals in box 124 occur for the pixel circuit. The charge is held in the storage node 251 until the row select signal Row_RS is pulsed. During this holding time, the negatively biased storage gate inhibits the generation of dark current which might flow to the storage node 251. The negatively biased gate of transfer transistor 248 also prevents charge leakage from the storage node 251 into the floating diffusion region. When the row in which the active pixel sensor is located is selected via row select signal Row_RS, reset signal Row_RST is momentarily made high so as to reset the floating diffusion region. A reset voltage associated with the reset floating diffusion region is output through the source follower transistor 244 and row select transistor 247 and sampled during a Sample_RST pulse. Then, transfer gate signal Row_TX, which is as negatively biased, is made high to transfer the generated charge into the floating diffusion region. Signal readout of a voltage associated with the charge stored in the floating diffusion region occurs through the source follower transistor 244 and row select transistor 246 and sampled during a pulse of the sample signal control signal Sample_Sig.

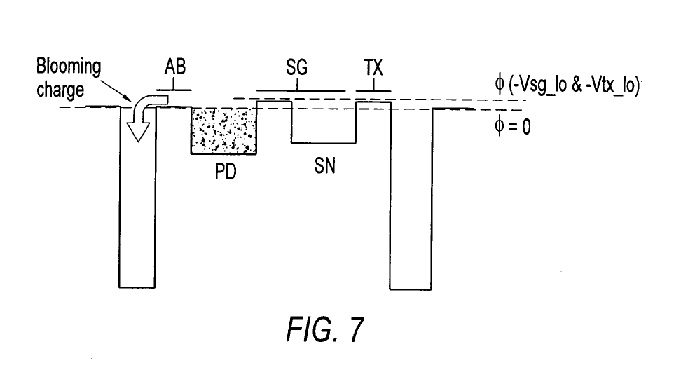

FIG. 7 is a potential diagram illustrating the relationship between the charge capacities of the photodiode 254, storage node 251 and floating diffusion region FD. As shown in FIG. 7, when the anti-blooming control signal AB is applied, charge is removed from the photodiode 254. Then, during an integration time, the photodiode 254 well PD accumulates charge based on incident light. If the photodiode 254 well PD exceeds its charge capacity, excess charge is allowed to leak through a partially “on” anti-blooming gate. Upon application of a storage gate control signal SG, the charge accumulated in the photodiode 254 well PD is transferred through the storage gate transistor 250 to the storage node 251 (SN). As soon as transfer is complete, the gate of storage gate transistor 250 is once again negatively biased. Because both the storage gate and the transfer gate are negatively biased, accumulating charge at the photodiode PD does not leak into the storage node and after charge is transferred to the storage node it does not leak into the floating diffusion region. Hence, the storage node maintains its full capacity. Moreover, dark current that might otherwise be generated at the storage gate of transistor 250 is inhibited. Charge is then transferred to the floating diffusion region upon application of the transfer control signal TX.

Although the transfer gate is negatively biased for the purpose of maintaining the charge capacity of the storage node, negatively biasing the transfer gate also results in hole h⁺ accumulation at the surface of the transfer gate, leading to the suppression of any additional dark current generated from the transfer gate.

Additionally, negatively biasing both the photodetector, as in the case of a photo gate pixel, or the storage node, as in the case of the storage gate pixel, and the transfer gate results in preserving the held charge in the photodetector or storage node from other possible contamination during the storage phase. The higher barriers caused by the negative bias makes the photodetector or storage node less susceptible to blooming from neighboring photodiodes during bright light conditions. The electrical cross-talk between the photodetector or storage node and the neighboring photodiode is also reduced due to the minimization of the depletion region at the photodetector or storage node/substrate junction. As a result, signal charge is preserved from other electrical contaminations during the time charge is held in the photodetector or storage node, thus improving the shutter efficiency. Shutter efficiency is defined as how intact the signal charge from the photodiode can be preserved during the storage phase.

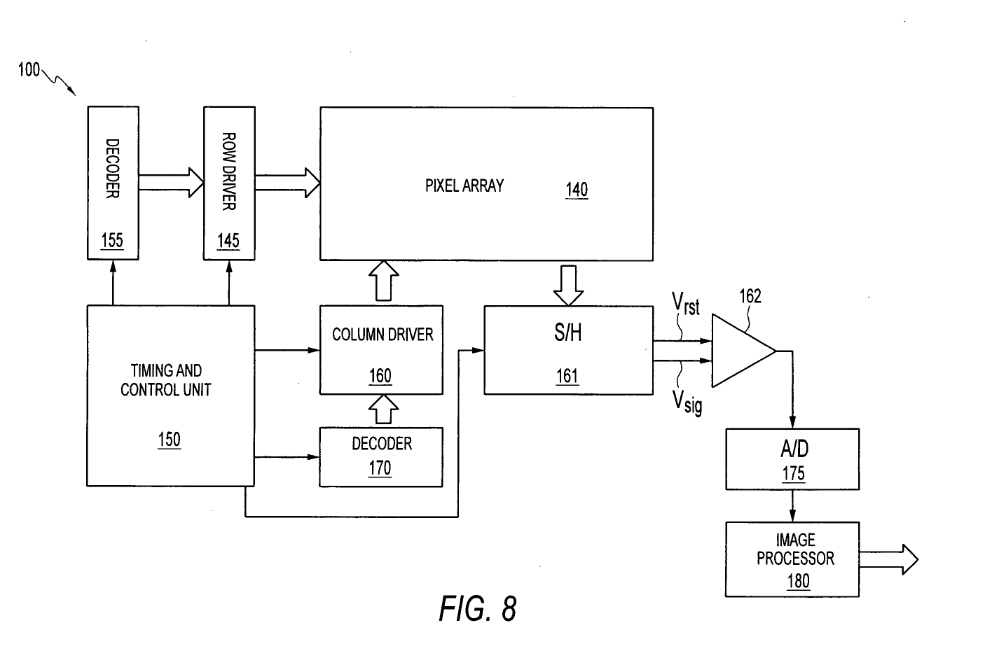

The exemplary embodiments of the invention presented above and other embodiments are implemented as pixel cells in, for example, a semiconductor imager. FIG. 8 illustrates a block diagram of an exemplary semiconductor CMOS imager 100 having a pixel array 140 comprising a plurality of pixel cells arranged in a predetermined number of columns and rows, and constructed in accordance with the invention. Each pixel cell is configured to receive incident photons and to convert the incident photons into electrical signals. Pixel cells of pixel array 140 are output row-by-row as activated by a row driver 145 in response to a row address decoder 155. Column driver 160 and column address decoder 170 are also used to selectively activate individual pixel columns. A timing and control circuit 150 controls address decoders 155, 170 for selecting the appropriate row and column lines for pixel readout. The control circuit 150 also controls the row and column driver circuitry 145, 160 such that driving voltages may be applied. The signals controlled by the control circuit 150 include the signals depicted in the timing diagrams of FIGS. 4 and 6. Each pixel cell generally outputs both a pixel reset signal Vᵣₛₜ and a pixel image signal V_{sig}, which are read by a sample and hold circuit 161. Vᵣₛₜ represents a reset state of a pixel cell. V_{sig} represents the amount of charge generated by the photosensor in a pixel cell in response to applied light during an integration period. The difference between V_{sig} and Vᵣₛₜ represents the actual pixel cell output with common-mode noise eliminated. The differential signal (Vᵣₛₜ−V_{sig}) is produced by differential amplifier 162 for each readout pixel cell. The differential signals are then digitized by an analog-to-digital converter 175. The analog-to-digital converter 175 supplies the digitized pixel signals to an image processor 180, which forms and outputs a digital image.

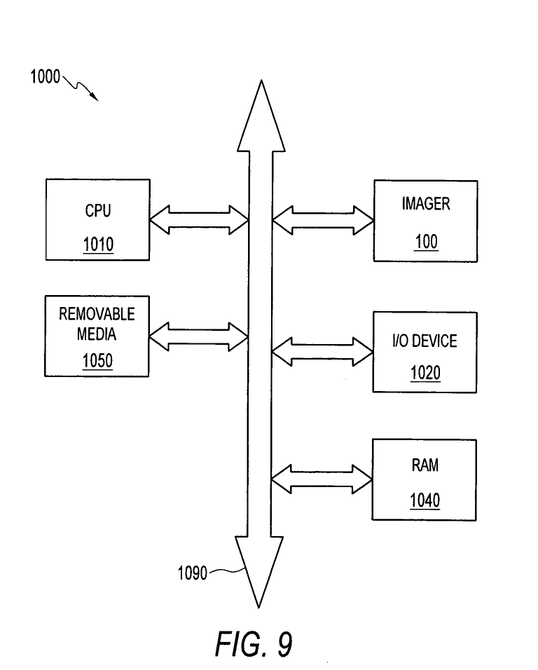

The storage gate or photo gate pixel circuits explained above may be used in any system which may employ an imager, including, but not limited to a computer system, camera system, scanner, machine vision, vehicle navigation, video phone, surveillance system, auto focus system, star tracker system, motion detection system, image stabilization system, and other imaging systems. Example digital camera systems in which the invention may be used include both still and video digital cameras, cell-phone cameras, handheld personal digital assistant (PDA) cameras, and other types of cameras. FIG. 9 shows a typical processor system 1000 which includes an imaging device 100 of FIG. 8 and which includes a pixel array having pixels constructed in accordance with the invention. The processor system 1000 is exemplary of a system having digital circuits that could include image sensor devices. System 1000, for example, a digital camera system, generally comprises a central processing unit (CPU) 1010, such as a microprocessor, that communicates with an input/output (I/O) device 1020 over a bus 1090. Imaging device 100 also communicates with the CPU 1010 over the bus 1090. The processor system 1000 also includes random access memory (RAM) 1040, and can include removable media 1050, such as flash memory, which also communicates with the CPU 1010 over the bus 1090. The imaging device 100 may be combined with a processor, such as a CPU, digital signal processor, or microprocessor, with or without memory storage on a single integrated circuit or on a different chip than the processor.

What is claimed as new and desired to be protected by Letters Patent of the United States is:

1. An imager comprising:
at least one pixel circuit comprising:
a photosensitive region for generating charge;
a holding region for holding said charge;
a gate associated with said holding region;
a floating diffusion region; and,
a transfer transistor for transferring said charge to said floating diffusion region; and,
a control circuit for negatively biasing said gate during an operational mode of said gate.

2. The imager of claim 1, wherein said control circuit is further operable to negatively bias a gate of said transfer transistor when said transfer transistor is off.

3. The imager of claim 2, wherein said photosensitive region, said holding region, and said gate are part of a photo gate structure, and said transfer transistor is operable to transfer charge from said photo gate holding region to said floating diffusion region.

4. The imager of claim 2, wherein said holding region is a storage node and said gate is part of a storage gate transistor which transfers charge to said storage node from said photosensitive region, said transfer transistor is operable to transfer charge from said storage node to said floating diffusion region.

5. The imager of claim 4, wherein said control circuit is further operable to negatively bias said gate of said storage gate transistor when said storage gate transistor is off.

6. The imager of claim 4, wherein said control circuit is further operable to negatively bias said gate of said storage gate transistor and said gate of said transfer transistor when said charge is held in said storage node.

7. The imager of claim 4, wherein said control circuit is further operable to convert a surface of said storage node into a holes-collecting region.

8. The imager of claim 2, further comprising an array of said pixel circuits, said control circuit being operable to negatively bias the gates of said pixel circuits during an operational mode of said gates, and being operable to negatively bias the gates of the transfer transistors of said pixel circuits when said transfer transistors are off.

9. The imager of claim 2, wherein said photosensitive region and said holding region are a same region.

10. The imager of claim 9, wherein said control circuit is further operable to negatively bias said gate during a time that said charge is generated and held in the same region.

11. The imager of claim 9, wherein said control circuit is further operable to convert a surface of said holding region into a holes-collecting region.

12. The imager of claim 2, wherein said control circuit is further operable to negatively bias said gate and said transfer transistor gate to a same level.

13. The imager of claim 2, wherein said control circuit is further operable to negatively bias said transfer transistor gate to a level more negative than a level to which said gate is biased.

14. A method of reducing dark current in a pixel circuit, comprising negatively biasing a gate associated with a holding region of said pixel circuit, said holding region configured to hold charge generated by a photosensitive region of the pixel circuit, said gate being negatively biased so as to also negatively bias a surface of said holding region proximate said gate.

15. The method of claim 14, further comprising negatively biasing a gate of a transfer transistor when said transfer transistor is off, said transfer transistor configured to transfer said charge from said holding region to a floating diffusion region.

16. The method of claim 15, wherein the act of negatively biasing a gate associated with a holding region further comprises negatively biasing a photo gate.

17. The method of claim 15, wherein the act of negatively biasing a gate associated with a holding region further comprises negatively biasing a storage gate of a storage gate transistor, said holding region being a storage node.

18. The method of claim 17, wherein said storage gate of said storage gate transistor is negatively biased when said storage gate transistor is off.

19. The method of claim 17, wherein said storage gate of said storage gate transistor and said gate of said transfer transistor are negatively biased when said charge is held in said storage node.

20. The method of claim 15, wherein the acts of negatively biasing said gate associated with said holding region and said gate of said transfer transistor include negatively biasing said holding region gate and said transfer transistor gate to a same level.

21. The method of claim 15, wherein the acts of negatively biasing said gate associated with said holding region and said gate of said transfer transistor include negatively biasing said transfer transistor gate to a level more negative than a level to which said holding region gate is biased.

22. A processing system, comprising:
at least one pixel circuit comprising:
a photosensitive region for generating charge;
a holding region for holding said charge;
a gate associated with said holding region; and,
a transfer transistor for transferring said charge from said holding region; and,
a processor configured to reduce dark current in said at least one pixel circuit by negatively biasing said gate.

23. The processing system of claim 22, wherein said processor is further configured to negatively bias a gate of said transfer transistor when said transfer transistor is off.

24. The processing system of claim 23, wherein said gate is a photo gate, and said processor is configured to negatively bias said photo gate.

25. The processing system of claim 23, wherein said gate is a storage gate of a storage gate transistor, and said holding region is a storage node.

26. The processing system of claim 25, wherein said processor is configured to negatively bias said storage gate transistor when said storage gate transistor is off.

27. The processing system of claim 25, wherein said processor is configured to negatively bias said storage gate transistor and said gate of said transfer transistor when said charge is held in said storage node.

28. The processing system of claim 23, wherein said processor is configured to negatively bias said holding region gate and said transfer transistor gate to a same level.

29. The processing system of claim 23, wherein said processor is configured to negatively bias said transfer transistor gate to a level more negative than a level to which said holding region gate is biased.

30. An imaging system, comprising:
an imager, comprising:
at least one pixel circuit comprising:
a photosensitive region for generating charge;
a holding region for holding said charge;
a gate associated with said holding region;
a floating diffusion region; and,
a transfer transistor for transferring said charge to said floating diffusion region; and,
a control circuit for negatively biasing said gate during an operational mode of said gate.

31. The imaging system of claim 30, wherein said control circuit is further operable to negatively bias a gate of said transfer transistor when said transfer transistor is off.

32. The imaging system of claim 31, wherein said photosensitive region, said holding region, and said gate are part of a photo gate structure, and said transfer transistor is operable to transfer charge from said photo gate holding region to said floating diffusion region.

33. The imaging system of claim 31, wherein said holding region is a storage node and said gate is part of a storage gate transistor which transfers charge to said storage node from said photosensitive region, said transfer transistor is operable to transfer charge from said storage node to said floating diffusion region.

34. The imaging system of claim 33, wherein said control circuit is further operable to negatively bias said gate of said storage gate transistor when said storage gate transistor is off.

35. The imaging system of claim 33, wherein said control circuit is further operable to negatively bias said gate of said storage gate transistor and said gate of said transfer transistor when said charge is held in said storage node.

36. The imaging system of claim 33, wherein said control circuit is further operable to convert a surface of said storage node into a holes-collecting region.

37. The imaging system of claim 31, further comprising an array of said pixel circuits, said control circuit being operable to negatively bias the gates of said pixel circuits during an operational mode of said gates, and being operable to negatively bias the gates of the transfer transistors of said pixel circuits when said transfer transistors are off.

38. The imaging system of claim 31, wherein said photosensitive region and said holding region are a same region.

39. The imaging system of claim 38, wherein said control circuit is further operable to negatively bias said gate during a time that said charge is generated and held in the same region.

40. The imaging system of claim 38, wherein said control circuit is further operable to convert a surface of said holding region into a holes-collecting region.

41. The imaging system of claim 31, wherein said control circuit is further operable to negatively bias said gate and said transfer transistor gate to a same level.

42. The imaging system of claim 31, wherein said control circuit is further operable to negatively bias said transfer transistor gate to a level more negative than a level to which said gate is biased.

43. A digital camera, comprising:
at least one pixel circuit comprising:
a photosensitive region for generating charge;
a holding region for holding said charge;
a gate associated with said holding region; and,
a control circuit for negatively biasing said gate during an operational mode of said gate.

44. The digital camera of claim 43, wherein the at least one pixel circuit further comprises:
a floating diffusion region; and,
a transfer transistor for transferring said charge to said floating diffusion region.

45. The digital camera of claim 44, wherein said control circuit is further operable to negatively bias a gate of said transfer transistor when said transfer transistor is off.

46. The digital camera of claim 45, wherein said photosensitive region, said holding region, and said gate are part of a photo gate structure, and said transfer transistor is operable to transfer charge from said photo gate holding region to said floating diffusion region.

47. The digital camera of claim 45, wherein said holding region is a storage node and said gate is part of a storage gate transistor which transfers charge to said storage node from said photosensitive region, said transfer transistor is operable to transfer charge from said storage node to said floating diffusion region.

48. The digital camera of claim 47, wherein said control circuit is further operable to negatively bias said gate of said storage gate transistor when said storage gate transistor is off.

49. The digital camera of claim 47, wherein said control circuit is further operable to negatively bias said gate of said storage gate transistor and said gate of said transfer transistor when said charge is held in said storage node.

50. The digital camera of claim 47, wherein said control circuit is further operable to convert a surface of said storage node into a holes-collecting region.

51. The digital camera of claim 45, further comprising an array of said pixel circuits, said control circuit being operable to negatively bias the gates of said pixel circuits during an operational mode of said gates, and being operable to negatively bias the gates of the transfer transistors of said pixel circuits when said transfer transistors are off.

52. The digital camera of claim 45, wherein said photosensitive region and said holding region are a same region.

53. The digital camera of claim 52, wherein said control circuit is further operable to negatively bias said gate during a time that said charge is generated and held in the same region.

54. The digital camera of claim 52, wherein said control circuit is further operable to convert a surface of said holding region into a holes-collecting region.

55. The digital camera of claim 45, wherein the camera is a still digital camera.

56. The digital camera of claim 45, wherein the camera is a video digital camera.

57. The digital camera of claim 45, wherein the camera is a cell-phone camera.

58. The digital camera of claim 45, wherein the camera is a handheld portable digital assistant (PDA) camera.
